(19) United States
(12) Patent Application Publication
(10) Pub. No.: US 2025/0040291 A1
(43) Pub. Date: Jan. 30, 2025

(54) PHOTODETECTOR

(71) Applicant: WUHAN OPTICAL VALLEY INFORMATION OPTOELECTRONICS INNOVATION CENTER CO., LTD, Wuhan, Hubei (CN)

(72) Inventors: Daigao CHEN, Wuhan (CN); Xi XIAO, Wuhan (CN); Min LIU, Wuhan (CN); Peiqi ZHOU, Wuhan (CN)

(21) Appl. No.: 18/716,534

(22) PCT Filed: Jan. 19, 2022
(86) PCT No.: PCT/CN2022/072641

§ 371 Date: Jun. 5, 2024

(30) Foreign Application Priority Data
Dec. 14, 2021 (CN) 202111530137.4

(51) Int. Cl. H01L 31/0232; H01L 31/0352; H01L 31/105

(52) U.S. Cl. CPC H01L 31/02327; H01L 31/035281; H01L 31/105

(57) ABSTRACT

A photodetector, comprising a flat slab structure (1), a waveguide structure (6), a light trapping structure (2), an absorption structure (3), a first electrode structure (4) and a second electrode structure (5), wherein the waveguide structure (6) extends into the light trapping structure (2), and a first edge where a first side wall of the waveguide structure (6) is located is tangent to a second edge where a second side wall in outer side walls of the light trapping structure (2) is located; the waveguide structure (6) is used for guiding incident light into the light trapping structure (2) in a direction tangent to the second edge; the guided light is trapped in the light trapping structure (2) by means of total internal reflection of the side walls of the light trapping structure (2) for annular transmission, and the guided light is coupled into the absorption structure (3) by means of the light trapping structure (2); the first electrode structure (4) is located in the light trapping structure (2); the first electrode structure (4) and the second electrode structure (5) are used for collecting electrons or holes transmitted along the absorption structure (3) and the light trapping structure (2); the types of current carriers collected by the first electrode structure (4) and the second electrode structure (5) are different.

### CROSS-REFERENCE TO RELATED APPLICATIONS

The application is based on and claims priority to Chinese Patent Application No. 202111530137.4 filed on Dec. 14, 2021 and entitled “Photodetector”, the entire contents of which are incorporated herein by reference in its entirety.

### TECHNICAL FIELD

The disclosure relates to the field of semiconductor technology, and in particular, to a photodetector.

### BACKGROUND

Borrowing ideas from the development route of large-scale integrated circuits, research is being carried out at home and abroad to integrate active devices (e.g., modulators, photodetectors, or the like) and optical waveguide devices (e.g., beamsplitters, couplers, or the like) onto a single substrate, in order to realize photonic chips that have advantages similar to those of large-scale integrated circuits. Photonic chips have characteristics of low cost, small size, low power consumption, flexible scaling and high reliability. Currently, silicon-based photonic chips are considered by the industry as the most promising photonic chips. Silicon-based photonic chips may combine microelectronics and optoelectronics, give full play to the advantages of silicon-based microelectronics, such as advanced and mature process technology, a high degree of integration, low cost, or the like, and have broad market prospects.

Silicon-based photonic chips generally adopt optical waveguides formed by Silicon On Insulator (SOI) materials. An optical waveguide is formed by a Si core layer and a SiO₂ cladding. The large difference of refractivity between the core layer and the cladding has a strong limiting effect on the light field, which may realize a waveguide bending radius of micrometer scale, thereby providing a realization basis for miniaturization and high-density integration of silicon-based photonic chips.

In the field of optical communication, a photodetector, such as a germanium-silicon waveguide-type photodetector, is often used as the receiving end of a silicon-based photonic chip. The germanium-silicon waveguide-type photodetector is a device that converts high-speed optical signals into current signals, and is a key device of the silicon-based photonic chip. The germanium-silicon waveguide-type photodetector mainly generates photocurrent by light absorption of the germanium material. In the related art, it is necessary to further improve the responsivity of the photodetector while taking into account the bandwidth of the photodetector.

### SUMMARY

In view of this, embodiments of the disclosure are expected to provide a photodetector.

In order to achieve the above purpose, the technical solution of the disclosure is implemented as follows.

The photodetector includes a slab structure, a waveguide structure, a light trapping structure, an absorption structure, a first electrode structure and a second electrode structure.

The waveguide structure extends into the light trapping structure. A first side, on which a first sidewall of the waveguide structure is positioned, is tangent to a second side, on which a second sidewall of outer sidewalls of the light trapping structure is positioned. The waveguide structure is configured to import incident light into the light trapping structure in a direction tangent to the second side.

The imported light is confined to travel annularly within the light trapping structure by total internal reflection of sidewalls of the light trapping structure, and the imported light is coupled into the absorption structure through the light trapping structure.

The absorption structure is at least partially positioned on the light trapping structure. The coupled light is confined to travel annularly within the absorption structure by total internal reflection of sidewalls of the absorption structure, and the coupled light is converted into electrons and holes.

The slab structure surrounds the waveguide structure and the light trapping structure.

The first electrode structure is positioned inside the light trapping structure. The second electrode structure is positioned outside the light trapping structure and is in contact with the light trapping structure. The first electrode structure and the second electrode structure are configured to collect electrons or holes flowing via the absorption structure and the light trapping structure. The first electrode structure and the second electrode structure collect different types of carriers.

In the above solution, the light trapping structure includes a first doped region and a second doped region surrounding the first doped region. The doping type of the first doped region is opposite to the doping type of the second doped region.

The first electrode structure is positioned inside the first doped region and is in contact with the first doped region, and the first electrode structure is configured to collect electrons or holes flowing via the absorption structure and the first doped region.

The second electrode structure is configured to collect electrons or holes flowing via the absorption structure and the second doped region.

In the above solution, the photodetector further includes an intrinsic region positioned between the first doped region and the second doped region.

The material of the intrinsic region is the same as the material of the light trapping structure; or
the material of the intrinsic region is the same as the material of the absorption structure.

In the above solution, the photodetector further includes a first intrinsic region and a second intrinsic region that are positioned between the first doped region and the second doped region, and the first intrinsic region and the second intrinsic region are sequentially stacked along the direction of the thickness of the light trapping structure.

The material of the first intrinsic region is the same as the material of the light trapping structure; and the material of the second intrinsic region is the same as the material of the absorption structure.

In the above solution, the sum of the projections of the first doped region, the intrinsic region, and the second doped region on a preset plane covers the projection of the absorption structure on the preset plane; and the projection of the absorption structure on the preset plane covers the projection of the intrinsic region on the preset plane.

The preset plane is perpendicular to the direction of the thickness of the light trapping structure.

In the above solution, the first electrode structure includes a first electrode, a first electrode contact region, and a third doped region. The third doped region is positioned inside the first doped region and is in contact with the first doped region. The first electrode contact region is positioned on the surface of the third doped region and a region with a certain depth downward from the surface of the third doped region, and the first electrode is positioned on the first electrode contact region. The first electrode is configured to collect electrons or holes flowing sequentially along the absorption structure, the first doped region, the third doped region, and the first electrode contact region.

The second electrode structure includes a second electrode, a second electrode contact region, and a fourth doped region. The fourth doped region surrounds the light trapping structure. The second electrode contact region is positioned on the surface of the fourth doped region and a region with a certain depth downward from the surface of the fourth doped region, and the second electrode is positioned on the second electrode contact region. The second electrode is configured to collect electrons or holes flowing sequentially along the absorption structure, the second doped region, and the fourth doped region.

In the above solution, the doping concentration of the second doped region is less than or equal to the doping concentration of the fourth doped region, and the doping concentration of the fourth doped region is less than the doping concentration of the second electrode contact region. The doping concentration of the first doped region is less than or equal to the doping concentration of the third doped region, and the concentration of the third doped region is less than the doping concentration of the first electrode contact region.

In the above solution, the first electrode contact region is remote from the absorption structure, and the thickness of the third doped region is less than or equal to the thickness of the light trapping structure. The thickness of the waveguide structure is the same as the thickness of the light trapping structure.

In the above solution, the shape of the projection of the waveguide structure on the preset plane includes an elongated shape.

The shape of the projection of the outer sidewalls of the light trapping structure on the preset plane includes an enclosed shape formed by at least one straight line and/or at least one curve. An angle formed by the second side, on which the second sidewall of the outer sidewalls of the light trapping structure is positioned, and a third side, on which a third sidewall of the outer sidewalls of the light trapping structure is positioned, is an obtuse angle.

The third sidewall is a sidewall where the incident light is reflected for the first time after the incident light enters the light trapping structure.

In the above solution, the shape of the projection of the outer sidewalls of the light trapping structure on the preset plane includes one of:
a circle;
an enclosed shape formed by connecting multiple curves;
an enclosed shape formed by connecting multiple straight lines and multiple curves; or
a polygon.

With the photodetector provided by the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure through the light trapping structure. Furthermore, the sides, on which the outer sidewalls of the light trapping structure and the absorption structure are positioned, adopt structures such as circular, optimally deformed circular-like or polygonal structures, which may confine light to be stably transmitted within an enclosed structure and reduce the excitation to high-order modes of the incident light during the propagation process in the light trapping structure and the absorption structure. In this way, the leakage of light may be reduced, and thereby the responsivity of the photodetector is improved. In addition, in the light trapping structure, the incident light can not escape from the light trapping structure in a first direction due to the total internal reflection effect of the sidewalls, and finally all of the incident light is coupled into the absorption structure. In the absorption structure, the incident light will also be confined within the absorption structure due to the total internal reflection effect of the sidewalls. In other words, the incident light propagates annularly in the light trapping structure and the absorption structure until the incident light is completely absorbed. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. In addition, in the embodiments of the disclosure, by setting the first electrode structure inside the light trapping structure, the contact between the absorption structure and the first electrode structure may be avoided, thereby reducing light loss generated by the contact between the absorption structure and the first electrode structure, and further improving the responsivity of the photodetector. Therefore, the photodetector provided by the embodiments of the disclosure may balance a high bandwidth and a high responsivity.

### BRIEF DESCRIPTION OF THE DRAWINGS

FIG. 1 is a schematic top view of a photodetector provided by an embodiment of the disclosure.

FIG. 2 is a schematic top view of another photodetector provided by an embodiment of the disclosure.

FIG. 3A and FIG. 3B are cross-sectional diagrams of FIG. 1 and FIG. 2 along the A1-A1 direction.

FIG. 4 is a cross-sectional diagram of FIG. 1 and FIG. 2 along the B1-B1 direction.

### DETAILED DESCRIPTION

The technical solutions of the disclosure are further illustrated in detail in combination with the drawings of the specification and specific embodiments.

In the description of the disclosure, it is to be understood that the terms “length”, “width”, “depth”, “upper”, “lower”, “outer”, or the like, indicate orientations or positional relationships based on those illustrated in the drawings, and are only intended to facilitate and simplify the description of the disclosure, instead of indicating or implying that the apparatus or element referred to must have a particular orientation, or be constructed and operated in a particular orientation, and thus can not be understood as a limitation on the disclosure.

In the embodiments of the disclosure, the term “substrate” refers to a material on which a subsequent material layer is added. The substrate itself may be patterned. The material added on the top of the substrate may be patterned or may be remained unpatterned. In addition, the substrate may include a variety of semiconductor materials, such as silicon, germanium, gallium arsenide, indium phosphide, or the like. Alternatively, the substrate may be made of a non-conductive material, such as glass, plastic, or a sapphire wafer.

In the embodiments of the disclosure, the term “layer” refers to a material part including a region with a thickness. A layer may extend on the entirety of an upper structure or a lower structure, or may have a scope that is smaller than the scope of the upper structure or the lower structure. In addition, a layer may be a region of a homogeneous or non-homogeneous continuous structure with a thickness less than the thickness of the continuous structure. For example, a layer may be positioned between the top surface and the bottom surface of the continuous structure, or a layer may be positioned between any pair of horizontal planes at the top surface and bottom surface of the continuous structure. A layer may extend horizontally, vertically, and/or along an inclined surface. A layer may include multiple sub-layers. For example, an interconnection layer may include one or more conductors and contact sub-layers (in which interconnection wires and/or via hole contacts are formed), and one or more dielectric sub-layers.

In the embodiments of the disclosure, the terms “first”, “second” or the like are used to distinguish similar objects, and need not to be used to describe a particular order or sequence.

It is to be noted that the technical solutions disclosed in the embodiments of the disclosure may be arbitrarily combined without conflict.

A germanium-silicon waveguide-type photodetector generally adopts a square structure, in which light is incident from one end of the light trapping structure, exits from the corresponding other end, and experiences one-way absorption. On one hand, in order to improve the responsivity of the photodetector, it is necessary to absorb as much light as possible, and thereby it is necessary to increase the size of the photodetector to obtain a larger responsivity. On the other hand, when the size of the photodetector is increased, the parasitic parameters of the photodetector will be increased, which will result in a decrease in the photoelectric bandwidth of the photodetector. In other words, currently, there is a mutual restrictive relationship between the responsivity and the photoelectric bandwidth of the photodetector. In addition, in a practical application, the metal electrode of the germanium-silicon waveguide-type photodetector is required to be contact with germanium and to be doped with germanium to form a P-I-N junction. However, the metal contact affects light absorption of the germanium, which causes light loss in the germanium absorption region and results in a decrease in the responsivity of the germanium-silicon waveguide-type photodetector.

In view of the above, the embodiments of the disclosure intend to provide a photodetector that balances a high bandwidth and a high responsivity. In the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure through the light trapping structure. Furthermore, the sides, on which the outer sidewalls of the light trapping structure and the absorption structure are positioned, adopt structures such as circular, optimally deformed circular-like or polygonal structures, which may confine light to be stably transmitted within an enclosed structure and reduce the excitation to high-order modes of the incident light during the propagation process in the light trapping structure and the absorption structure. In this way, the leakage of light may be reduced, and thereby the responsivity of the photodetector is improved. In addition, in the light trapping structure, the incident light can not escape from the light trapping structure in a first direction due to the total internal reflection effect of the sidewalls, and finally all of the incident light is coupled into the absorption structure. In the absorption structure, the incident light will also be confined within the absorption structure due to the total internal reflection effect of the sidewalls. In other words, the incident light propagates annularly in the light trapping structure and the absorption structure until the incident light is completely absorbed. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. In addition, in the embodiments of the disclosure, by setting the first electrode structure inside the light trapping structure and to be in contact with the light trapping structure, the contact between the absorption structure and the first electrode structure may be avoided, thereby reducing light loss generated by the contact between the absorption structure and the first electrode structure, and further improving the responsivity of the photodetector. Therefore, the photodetector provided by the embodiments of the disclosure may balance a high bandwidth and a high responsivity.

An embodiment of the disclosure provides a photodetector that includes a slab structure, a waveguide structure, a light trapping structure, an absorption structure, a first electrode structure and a second electrode structure.

The waveguide structure extends into the light trapping structure. A first side, on which a first sidewall of the waveguide structure is positioned, is tangent to a second side, on which a second sidewall of outer sidewalls of the light trapping structure is positioned. The waveguide structure is configured to import incident light into the light trapping structure in a direction tangent to the second side.

The imported light is confined to travel annularly within the light trapping structure by total internal reflection of sidewalls of the light trapping structure, and the imported light is coupled into the absorption structure through the light trapping structure.

The absorption structure is at least partially positioned on the light trapping structure. The coupled light is confined to travel annularly within the absorption structure by total internal reflection of sidewalls of the absorption structure, and the coupled light is converted into electrons and holes.

The slab structure surrounds the waveguide structure and the light trapping structure.

The first electrode structure is positioned inside the light trapping structure. The second electrode structure is positioned outside the light trapping structure and is in contact with the light trapping structure. The first electrode structure and the second electrode structure are configured to collect electrons or holes flowing via the absorption structure and the light trapping structure. The first electrode structure and the second electrode structure collect different types of carriers.

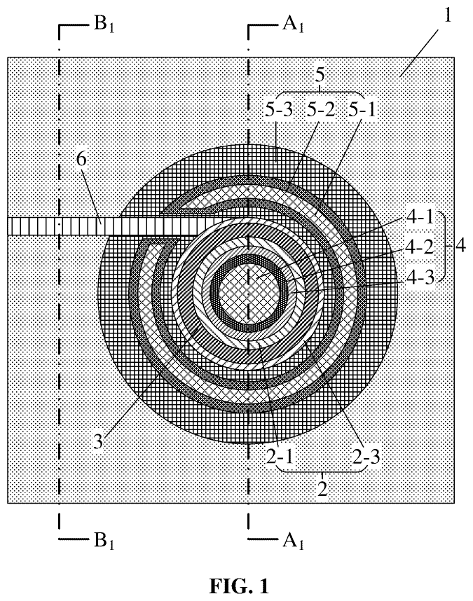

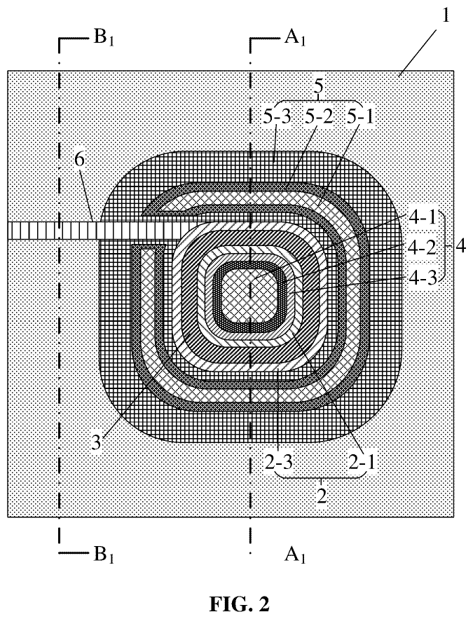

FIG. 1 is a schematic top view of a photodetector provided by an embodiment of the disclosure, and FIG. 2 is a schematic top view of another photodetector provided by an embodiment of the disclosure. It is to be noted that the structures of the photodetectors illustrated in FIG. 1 and FIG. 2 are similar, and the difference is mainly embodied in the shapes of the projections of the light trapping structure 2 and the absorption structure 3 on the preset plane. The photodetector will be exemplarily described below according to FIG. 1.

As illustrated in FIG. 1, the photodetector includes a slab structure 1, a waveguide structure 6, a light trapping structure 2, an absorption structure 3, a first electrode structure 4 and a second electrode structure 5. The waveguide structure 6 extends into the light trapping structure 2. A first side, on which a first sidewall of the waveguide structure 6 is positioned, is tangent to a second side, on which a second sidewall of outer sidewalls of the light trapping structure 2 is positioned. The waveguide structure 6 is configured to import incident light into the light trapping structure 2 in a direction tangent to the second side. The imported light is confined to travel annularly within the light trapping structure 2 by total internal reflection of sidewalls of the light trapping structure 2, and the imported light is coupled into the absorption structure through the light trapping structure 2. The absorption structure 3 is positioned on the light trapping structure 2. The coupled light is confined to travel annularly within the absorption structure 3 by total internal reflection of sidewalls of the absorption structure 3, and the coupled light is converted into electrons and holes. The slab structure 1 surrounds the waveguide structure 6 and the light trapping structure 2. The first electrode structure 4 is positioned inside the light trapping structure 2. The second electrode structure 5 is positioned outside the light trapping structure 2 and is in contact with the light trapping structure 2. The first electrode structure 4 and the second electrode structure 5 are configured to collect electrons or holes flowing via the absorption structure 3 and the light trapping structure 2. The first electrode structure 4 and the second electrode structure 5 collect different types of carriers.

In a practical application, the waveguide structure 6 is configured to propagate incident light, and the incident light enters the light trapping structure through the waveguide structure 6. The waveguide structure 6 may be a silicon waveguide, and the silicon waveguide includes a silicon (Si) core layer and a silicon dioxide (SiO₂) cladding. Here, the waveguide structure 6 extends into the light trapping structure 2. The first side, on which the first sidewall of the waveguide structure 6 is positioned, is tangent to the second side, on which the second sidewall of the light trapping structure 2 is positioned. The waveguide structure 6 is configured to import incident light into the light trapping structure 2 in the direction tangent to the second side. It is to be understood that the incident light may be imported into the light trapping structure 2 through the waveguide structure 6 in a direction tangent to an outer sidewall of the light trapping structure 2, which reduces the mutation affect of the incident light during the propagation process in the waveguide structure 6 and the light trapping structure 2. In this way, the high-order modes of the light excited during the propagation process are reduced, the stability of the incident light during the propagation process is improved, the leakage of light is reduced, and the responsivity of the photodetector is improved.

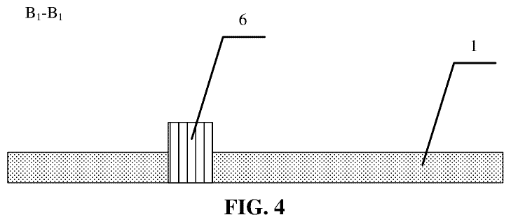

In a practical application, as illustrated in FIG. 4, the thickness of the slab structure 1 is less than the thickness of the waveguide structure 6. The slab structure 1 and the waveguide structure 6 form a rib incident waveguide, the incident waveguide is a silicon waveguide for propagating incident light, and the incident light enters the light trapping structure 2 through the incident waveguide and is coupled into the absorption structure 3. It is to be noted that the specific structure of the incident waveguide is not limited in the embodiments of the disclosure. Specifically, the photodetector in the embodiments of the disclosure may include a rib incident waveguide or a waveguide of other shapes. Here, the solution provided by the embodiments of the disclosure is exemplarily described only with a germanium-silicon waveguide-type photodetector that has a rib incident waveguide.

In a practical application, the light trapping structure 2 is configured to receive the incident light propagated by the incident waveguide, and to confine the imported light to travel annularly within a coupling structure in a first direction by total internal reflection of the sidewalls, and further, to couple the imported light into the absorption structure 3 through the light trapping structure. Here, the material of the light trapping structure 2 may include lightly doped silicon.

It is to be understood that the incident light is confined to travel annularly within the coupling structure in the first direction by the total internal reflection effect of the sidewalls of the light trapping structure 2, while all of the incident light is coupled into the absorption structure 3 through the light trapping structure 2, and then all of the incident light is absorbed by the absorption structure 3. In the embodiments of the disclosure, the light trapping structure 2 coupling all of the imported light into the absorption structure 3 may be understood as follows. From the perspective of theoretical design, the light entering the light trapping structure 2 may be 100% coupled into the absorption structure 3. However, in a practical application, due to the process and other factors, such as the inevitable presence of a very small amount of scattering on the reflecting surface, or absorption of the doped region, the light entering the light trapping structure 2 can not 100% completely enter the absorption structure 3. The above caused light loss is not included in the above meaning of “all”.

It is to be noted that in case that the light trapping structure 2 and the absorption structure 3 are set to be stacked, the first direction is perpendicular to the stacking direction. It is to be understood that in case that the light trapping structure 2 and the absorption structure 3 are set to be stacked vertically, the first direction is the horizontal direction.

In a practical application, the absorption structure 3 is positioned on the light trapping structure 2, and is configured to confine the coupled light to travel annularly within the absorption structure 3 in the first direction by the total internal reflection of the sidewalls and to convert the coupled light into electrons and holes. Here, the absorption structure 3 may include a germanium absorption region.

In a practical application, the slab structure 1 surrounds the waveguide structure 6 and the light trapping structure 2, and the thickness of the slab structure 1 is less than the thickness of the light trapping structure 2. It is to be understood that the slab structure 1 and the light trapping structure 2 form a rib waveguide structure.

In a practical application, the first electrode structure 4 is positioned inside the light trapping structure 2 and is in contact with the light trapping structure 2, and the second electrode structure 5 is positioned in the slab structure 1 and the second electrode structure 5 surrounds the light trapping structure 2. The first electrode structure 4 and the second electrode structure 5 are configured to collect electrons or holes flowing via the absorption structure 3 and the light trapping structure 2, and the first electrode structure 4 and the second electrode structure 5 collect different types of carriers. For example, electron-hole pairs generated by photons move towards the poles under the action of an applied electric field. In case that the carriers collected by the first electrode structure 4 are electrons, the carriers collected by the second electrode structure 5 are holes. Alternatively, in case that the carriers collected by the first electrode structure 4 are holes, the carriers collected by the second electrode structure 5 are electrons.

Here, the first electrode structure 4 and the second electrode structure 5 include a metal electrode. The first electrode structure 4 is positioned inside the light trapping structure 2 and is in contact with the light trapping structure 2, thereby avoiding the contact between the germanium absorption region and the metal electrode, reducing the optical absorption of the metal electrode, and further improving the responsivity. In addition, no ohmic contact between germanium and metal is required, which enables a simple process and low costs.

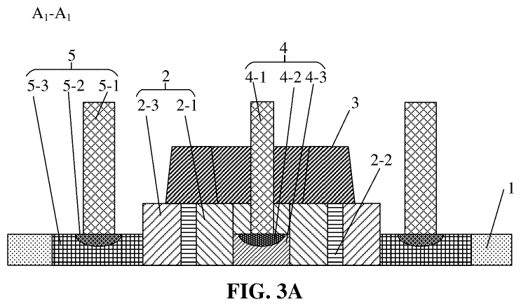

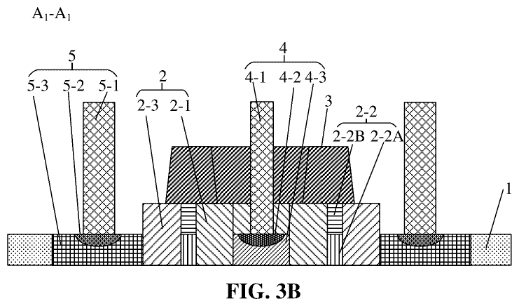

FIG. 3A and FIG. 3B are cross-sectional diagrams of FIG. 1 and FIG. 2 along the A1-A1 direction. In an embodiment, as illustrated in FIG. 3A and FIG. 3B, the light trapping structure 2 includes a first doped region 2-1 and a second doped region 2-3 surrounding the first doped region 2-1. The doping type of the first doped region 2-1 is opposite to the doping type of the second doped region 2-3. The first electrode structure 4 is positioned inside the first doped region 2-1 and is in contact with the first doped region 2-1, and the first electrode structure 4 is configured to collect electrons or holes flowing via the absorption structure 3 and the first doped region 2-1. The second electrode structure 5 is configured to collect electrons or holes flowing via the absorption structure 3 and the second doped region 2-3.

In a practical application, as illustrated in FIG. 1, both the first doped region 2-1 and the second doped region 2-3 include an annular waveguide structure. The doping type of the annular waveguide structure of the first doped region 2-1 is opposite to the doping type of the annular waveguide structure of the second doped region 2-3.

Here, both the projection of the annular waveguide structure of the first doped region 2-1 on the preset plane and the projection of the second doped region 2-3 annular waveguide structure on the preset plane include an annular shape. In a practical application, the projection of the annular waveguide structure of the first doped region 2-1 on the preset plane and the projection of the annular waveguide structure of the second doped region 2-3 on the preset plane include an enclosed shape such as a deformed annular shape as illustrated in FIG. 2, a regular polygonal annular shape, or the like. It is to be noted that since the annular waveguide structure of the first doped region 2-1 surrounds a portion of the first electrode structure 4, the inner side of the annular waveguide structure of the first doped region 2-1 overlaps with the outer side of the portion of the first electrode structure 4. Therefore, the projection of the annular waveguide structure of the first doped region 2-1 on the preset plane varies according to the shape of the first electrode structure 4.

In an embodiment, as illustrated in FIG. 3A, the photodetector further includes an intrinsic region 2-2 positioned between the first doped region 2-1 and the second doped region 2-3. The material of the intrinsic region 2-2 is the same as the material of the light trapping structure 2, or the material of the intrinsic region 2-2 is the same as the material of the absorption structure 3.

In a practical application, the intrinsic region 2-2 includes an annular waveguide structure. In case that the material of the intrinsic region 2-2 is the same as the material of the light trapping structure 2, the light trapping structure 2 includes the annular waveguide structure of the first doped region 2-1, the annular waveguide structure of the intrinsic region 2-2, and the annular waveguide structure of the second doped region 2-3. In case that the material of the intrinsic region 2-2 is the same as the material of the absorption structure 3, the absorption structure 3 further includes the annular waveguide structure of the intrinsic region 2-2. Here, the inner side of the annular waveguide structure of the second doped region 2-3 overlaps with the outer side of the annular waveguide structure of the intrinsic region 2-2, and the inner side of the annular waveguide structure of the intrinsic region 2-2 overlaps with the outer side of the annular waveguide structure of the first doped region 2-1. It is to be understood that the intrinsic region 2-2 between the first doped region 2-1 and the second doped region 2-3 increases the electric field intensity in the absorption structure 3, thereby increases the flow velocity of carriers, and thus the bandwidth of the detector is increased. In addition, during the design process of the photodetector, a greater degree of freedom may be provided for the design of the dimensions of the photodetector by adjusting the width of the intrinsic region 2-2.

In an embodiment, as illustrated in FIG. 3b, the photodetector further includes a first intrinsic region 2-2A and a second intrinsic region 2-2B that are positioned between the first doped region 2-1 and the second doped region 2-3, and the first intrinsic region 2-2A and the second intrinsic region 2-2B are sequentially stacked along the direction of the thickness of the light trapping structure 2. The material of the first intrinsic region 2-2A is the same as the material of the light trapping structure 2; and the material of the second intrinsic region 2-2B is the same as the material of the absorption structure 3. In other words, the light trapping structure 2 further includes the first intrinsic region 2-2A, and the absorption structure 3 further includes the second intrinsic region 2-2B.

In an embodiment, the sum of the projections of the first doped region 2-1, the intrinsic region 2-2, and the second doped region 2-3 on a preset plane covers the projection of the absorption structure 3 on the preset plane; and the projection of the absorption structure 3 on the preset plane covers the projection of the intrinsic region 2-2 on the preset plane. The preset plane is perpendicular to the direction of the thickness of the light trapping structure 2. It is to be understood that the area of the sum of the projections of the first doped region 2-1, the intrinsic region 2-2 and the second doped region 2-3 on the preset plane is larger than the area of the projection of the absorption structure 3 on the preset plane, which may better provide a growth platform for the absorption structure 3. The projection of the absorption structure 3 on the preset plane covers the projection of the intrinsic region 2-2 on the preset plane. It is to be noted that the sum of the projections of the first doped region 2-1, the intrinsic region 2-2 and the second doped region 2-3 on the preset plane includes the projection obtained by superimposing the projection of the first doped region 2-1 on the preset plane, the projection of the intrinsic region 2-2 on the preset plane, and the projection of the second doped region 2-3 on the preset plane.

In an embodiment, as illustrated in FIG. 1, FIG. 3A and FIG. 3B, the first electrode structure 4 includes a first electrode 4-1, a first electrode contact region 4-2, and a third doped region 4-3. The third doped region 4-3 is positioned inside the annular waveguide structure of the first doped region 2-1, and the inner side of the annular waveguide structure of the first doped region 2-1 overlaps with the outer side of the third doped region 4-3. The first electrode contact region 4-2 is positioned on the surface of the third doped region 4-3 and a region with a certain depth downward from the surface of the third doped region 4-3, and the first electrode 4-1 is positioned on the first electrode contact region 4-2. The first electrode 4-1 is configured to collect electrons or holes flowing sequentially along the absorption structure 3, the first doped region 2-1, the third doped region 4-3, and the first electrode contact region 4-2. The second electrode structure 5 includes a second electrode 5-1, a second electrode contact region 5-2, and a fourth doped region 5-3. The fourth doped region 5-3 surrounds the light trapping structure 2, the second electrode contact region 5-2 is positioned on the surface of the fourth doped region 5-3 and a region with a certain depth downward from the surface of the fourth doped region 5-3, and the second electrode 5-1 is positioned on the second electrode contact region 5-2. The second electrode 5-1 is configured to collect electrons or holes flowing sequentially along the absorption structure 3, the second doped region 2-3 and the fourth doped region 5-3. Here, the projection of the second electrode 5-1 on the preset plane is annular and remote from the light trapping structure 2. It is to be noted that the specific shapes of the first electrode 4-1 and the second electrode 5-1 vary according to the shape of the electrode contact region and are not limited to the specific embodiments of the disclosure.

In a practical application, the doping concentration of the first electrode contact region 4-2 may be higher than the doping concentration of the third doped region 4-3, and the doping concentration of the second electrode contact region 5-2 may be higher than the doping concentration of the fourth doped region 5-3, so as to reduce the resistance of the first electrode contact region 4-2 and the second electrode contact region 5-2, to form good ohmic contact between the electrode and the electrode contact region, and to further increase the bandwidth of the photodetector.

In an embodiment, the doping concentration of the second doped region 2-3 is less than or equal to the doping concentration of the fourth doped region 5-3, and the doping concentration of the first doped region 2-1 is less than or equal to the doping concentration of the third doped region 4-3.

It is to be noted that in order to reduce the absorption loss of light within the light trapping structure 2, the doping concentration of the second doped region 2-3 positioned in the light trapping structure 2 is less than or equal to the doping concentration of the fourth doped region 5-3. In addition, the doping concentration of the first doped region 2-1 positioned in the light trapping structure 2 is less than or equal to the doping concentration of the third doped region 4-3.

In an embodiment, the thickness of the third doped region is less than or equal to the thickness of the light trapping structure 2. In this way, the excitation to high-order modes of light may be further reduced and the leakage of light may be reduced, thereby further improving the responsivity of the photodetector.

In an embodiment, the thickness of the waveguide structure 6 is the same as the thickness of the light trapping structure 2. In a practical application, the thickness of the waveguide structure 6 is the same as the thickness of the light trapping structure 2, and the thickness of the waveguide structure 6 is greater than the thickness of the slab structure 1. In this way, reflection and refraction of light at the entrance where the light enters the light trapping structure 2 from the waveguide structure 6 may be reduced, thereby reducing the leakage of light.

In an embodiment, the shape of the projection of the waveguide structure 6 on the preset plane includes an elongated strip. The shape of the projection of the outer sidewalls of the light trapping structure 2 on the preset plane includes an enclosed shape formed by at least one straight line and/or at least one curve, and the angle formed by the second side, on which the second sidewall of the outer sidewalls of the light trapping structure 2 is positioned, and a third side, on which a third sidewall of the outer sidewalls of the light trapping structure 2 is positioned, is an obtuse angle. The third sidewall is a sidewall where the incident light is reflected for the first time after the incident light enters the light trapping structure 2.

In a practical application, in case that the projection of the outer sidewalls of the light trapping structure 2 on the preset plane includes a straight line, the first side, on which the first sidewall of the waveguide structure 6 is positioned, is tangent to the straight line. In case that the projection of a sidewall of the light trapping structure 2 on the preset plane is only a curve, the first side, on which the first sidewall of the waveguide structure 6 is positioned, is tangent to the curve.

Here, in case that the sides, on which the outer sidewalls of the light trapping structure 2 are positioned, include multiple straight lines, the angle formed by the second side, on which the second sidewall of the outer sidewalls of the light trapping structure is positioned, and the third side, on which the third sidewall of the outer sidewalls of the light trapping structure is positioned, is an obtuse angle. In case that the sides, on which the outer sidewalls of the light trapping structure 2 are positioned, include at least one curve, either the second side, on which the second sidewall of the outer sidewalls of the light trapping structure is positioned, or the third side, on which the third sidewall of the outer sidewalls of the light trapping structure is positioned, may be regarded as an side on which the curve is positioned. It is to be noted that a curve may be regarded as a figure consisting of countless straight lines. It is to be understood that the reflection angle where the incident light is reflected for the first time after the incident light enters the light trapping structure is not equal to 0 degree. In other words, after entering the light trapping structure, the incident light will not be reflected back directly from the entrance of the incident light, thereby avoiding the leakage of light from the entrance of the incident light.

In an embodiment, the shape of the projection of the outer sidewalls of the light trapping structure 2 on the preset plane includes one of:
a circle;
an enclosed shape formed by connecting multiple curves;
an enclosed shape formed by connecting multiple straight lines and multiple curves; or
a polygon.

It is to be noted that in some embodiments, the light trapping structure 2 further includes inner sidewalls. The shape of the projection of the inner sidewalls of the light trapping structure 2 on the preset plane may be the same as or different from the shape of the projection of the outer sidewalls of the light trapping structure 2 on the preset plane. Specifically, in case that the shape of the projection of the outer sidewalls of the light trapping structure 2 on the preset plane includes a circle, the shape of the projection of the inner sidewalls of the light trapping structure 2 on the preset plane may be a circle, a polygon or of other shapes. In case that the shape of the projection of the inner sidewalls of the light trapping structure 2 on the preset plane may be a circle, the projection of the light trapping structure 2 on the preset plane is annular. In a practical application, the projection of the light trapping structure 2 on the preset plane may include an annular shape or multiple concentric annular shapes.

In a practical application, the projections of the outer sidewalls and the inner sidewalls of the light trapping structure 2 on the preset plane include a variety of different shapes. In the following embodiments, the shape of the projection of the outer sidewalls of the light trapping structure 2 on the preset plane will be taken as an example to illustrate different shapes of the projection of the light trapping structure 2 on the preset plane. It is to be noted that in the following embodiments, the shape of the projection of the inner sidewalls of the light trapping structure 2 on the preset plane is the same as that of the outer sidewalls and will not be repeated herein.

In an embodiment, as illustrated in FIG. 1, the shape of the projection of the outer sidewalls of the light trapping structure 2 on the preset plane is a circle. The waveguide structure 6 extends into the light trapping structure 2, and the first side, on which the first sidewall of the waveguide structure 6 is positioned, is tangent to the round side of the light trapping structure 2. It is to be understood that in case that the shapes of the projections of both the outer sidewalls and the inner sidewalls of the light trapping structure 2 on the preset plane are circles, the shape of the projection of the light trapping structure 2 on the preset plane is an annular shape. In this way, the incident light propagates annularly in the annular light trapping structure 2, and thus the size of the photodetector may be reduced, thereby reducing the parasitic parameters of the photodetector, and enabling the photodetector to have a higher bandwidth. Here, the preset plane is perpendicular to the direction of the thickness of the light trapping structure, and the plane, on which the slab structure 1 is positioned, is parallel to the preset plane.

In a practical application, the projection of the outer sidewalls of the light trapping structure 2 on the preset plane includes an enclosed shape formed by connecting multiple curves. Different cases of the enclosed shape formed by connecting multiple curves will be illustrated in detail below.

In an embodiment, the shape of the projection of the outer sidewalls of the light trapping structure 2 on the preset plane is an enclosed shape formed by connecting multiple curves. The waveguide structure 6 extends into the light trapping structure 2, and the first side, on which the first sidewall of the waveguide structure 6 is positioned, is tangent to one of the multiple curves. The one of the multiple curves has a radius of curvature approaching infinity at the point of tangency. Each of the multiple curves includes a first sub-curve and a second sub-curve that are identical. The radius of curvature of the first sub-curve approaches infinity at a first endpoint, and the radius of curvature of the first sub-curve gradually decreases from the first endpoint to a second endpoint where the first sub-curve is connected to the second sub-curve.

In an embodiment, the shape of the projection of the outer sidewalls of the light trapping structure 2 on the preset plane is an enclosed shape formed by connecting four identical curves. The curves bend at an angle of 90 degrees, and each of the four curves is divided into two identical sub-curves by a 45-degree equidistant line. Any one of the sub-curves has a radius of curvature which gradually decreases as the sub-curve approaches towards the 45-degree equidistant line from the endpoint of the sub-curve remote from the 45-degree equidistant line, and the radius of curvature decreases to a certain value when the sub-curve reaches the 45-degree equidistant line. The radius of curvature of the shape of the projection of the light trapping structure 2 on the preset plane varies gradually, thereby avoiding the generation of more high-order modes when light propagates in the light trapping structure 2, which is conducive to reducing the leakage of light.

In an embodiment, the shape of the projection of the outer sidewalls of the light trapping structure 2 on the preset plane is an enclosed shape formed by connecting four identical curves. The curves bend at an angle of 90 degrees, and each of the four curves has a 45-degree equidistant line. Each of the four curves is divided into a third sub-curve, a fourth sub-curve and a fifth sub-curve sequentially from a first endpoint to a second endpoint. The third sub-curve and the fifth sub-curve have radii of curvature which gradually decrease as they approach towards the 45-degree equidistant line from the first endpoint and the second endpoint respectively, and the third sub-curve and the fifth sub-curve are connected by the fourth sub-curve when they do not reach the 45-degree equidistant line. The radii of curvature at the two endpoints of the fourth sub-curve are equal to the radius of curvature of the third sub-curve at the endpoint close to the 45-degree equidistant line and the radius of curvature of the fifth sub-curve at the endpoint close to the 45-degree equidistant line, respectively. The radius of curvature of the shape of the projection of the light trapping structure 2 on the preset plane varies uniformly, thereby avoiding the generation of more high-order modes when light propagates in the light trapping structure 2, which is conducive to reducing the leakage of light.

In a practical application, the projection of the outer sidewalls of the light trapping structure 2 on the preset plane includes an enclosed shape formed by connecting multiple straight lines and multiple curves. Different cases of the enclosed shape formed by connecting multiple straight lines and multiple curves will be illustrated in detail below.

In an embodiment, the shape of the projection of the outer sidewalls of the light trapping structure 2 on the preset plane is an enclosed shape formed by connecting multiple straight lines and multiple curves. The waveguide structure 6 extends into the light trapping structure 2, and the first side, on which the first sidewall of the waveguide structure 6 is positioned, overlaps with one of the straight lines of the enclosed shape.

In an embodiment, the shape of the projection of the outer sidewalls of the light trapping structure 2 on the preset plane is an enclosed shape formed by alternately connecting multiple straight lines and multiple curves. Each of the multiple curves includes a sixth sub-curve and a seventh sub-curve that are identical. The radius of curvature of the sixth sub-curve gradually decreases from a first endpoint where the sixth sub-curve is tangent to the straight line, to a second endpoint where the sixth sub-curve is connected to the seventh sub-curve.

In an embodiment, as illustrated in FIG. 2, the shape of the projection of the outer sidewalls of the light trapping structure 2 on the preset plane is an enclosed shape formed by alternately connecting four identical straight lines and four identical curves. The waveguide structure 6 extends into the light trapping structure 2, and the first side, on which the first sidewall of the waveguide structure 6 is positioned, overlaps with one of the straight lines of the enclosed shape. It is to be understood that the incident light propagates straight at least along one of the straight sides when entering the light trapping structure 2, and subsequently propagates annularly in the light trapping structure 2 formed by the enclosed shape. Therefore, on one hand, the high-order modes of the light excited during the propagation process may be reduced, the leakage of light may be reduced, and the responsivity of the photodetector may be improved. On the other hand, the size of the photodetector may be reduced, thereby reducing the parasitic parameters of the photodetector and enabling the photodetector to have a higher bandwidth.

In an embodiment, the shape of the projection of the outer sidewalls of the light trapping structure 2 on the preset plane is an enclosed shape formed by alternately connecting four identical straight lines and four identical curves. The curves bend at an angle of 90 degrees, and each of the four curves is divided into two identical sub-curves by a 45-degree equidistant line. Any one of the sub-curves has a radius of curvature which gradually decreases as the sub-curve approaches towards the 45-degree equidistant line from the endpoint of the sub-curve remote from the 45-degree equidistant line, and the radius of curvature decreases to a certain value when the sub-curve reaches the 45-degree equidistant line. The radius of curvature of the shape of the projection of the light trapping structure 2 on the preset plane varies gradually, thereby avoiding the generation of more high-order modes when light propagates in the light trapping structure 2, which is conducive to reducing the leakage of light.

In an embodiment, the shape of the projection of the outer sidewalls of the light trapping structure 2 on the preset plane is an enclosed shape formed by alternately connecting four identical straight lines and four identical curves. The curves bend at an angle of 90 degrees, and each of the four curves has a 45-degree equidistant line. Each of the four curves is divided into an eighth sub-curve, a ninth sub-curve and a tenth sub-curve sequentially from a first endpoint to a second endpoint. The eighth sub-curve and the tenth sub-curve have radii of curvature which gradually decrease as they approach towards the 45-degree equidistant line from the first endpoint and the second endpoint respectively, and the eighth sub-curve and the tenth sub-curve are connected by the ninth sub-curve when they do not reach the 45-degree equidistant line. The radii of curvature at the two endpoints of the ninth sub-curve are equal to the radius of curvature of the eighth sub-curve at the endpoint close to the 45-degree equidistant line and the radius of curvature of the tenth sub-curve at the endpoint approaching the 45-degree equidistant line, respectively. The radius of curvature of the shape of the projection of the light trapping structure 2 on the preset plane varies uniformly, thereby avoiding the generation of more high-order modes when light propagates in the light trapping structure 2, which is conducive to reducing the leakage of light.

In a practical application, the projection of the outer sidewalls of the light trapping structure 2 on the preset plane includes a polygon. Different cases where the projection includes a polygon will be illustrated in detail below.

In an embodiment, the shape of the projection of the outer sidewalls of the light trapping structure 2 on the preset plane is a polygon. The waveguide structure 6 extends into the light trapping structure 2, and the first side, on which the first sidewall of the waveguide structure 6 is positioned, overlaps with one of the sides of the polygon. The angle formed by the second side, on which the second sidewall of the outer sidewalls of the light trapping structure 2 is positioned, and the third side, on which the third sidewall of the outer sidewalls of the light trapping structure 2 is positioned, is an obtuse angle. The third sidewall is a sidewall where the incident light is reflected for the first time after the incident light enters the light trapping structure 2. It is to be understood that the reflection angle where the incident light is reflected for the first time after the incident light enters the light trapping structure 2 is not equal to 0 degree. In other words, after entering the light trapping structure 2, the incident light will not be reflected back from the entrance of the incident light, thereby avoiding the leakage of light from the entrance of the incident light.

In an embodiment, the polygon includes a regular polygon and has a number of sides greater than or equal to 6.

In an embodiment, the shape of the projection of the outer sidewalls of the light trapping structure 2 on the preset plane is a regular octagon. The waveguide structure 6 extends into the light trapping structure 2, and the first side, on which the first sidewall of the waveguide structure 6 is positioned, is tangent to one of the sides of the regular octagon. The incident light propagates annularly along the regular octagon after entering the light trapping structure 2 from the waveguide structure 6.

Different cases of the shape of the projection of the outer sidewalls of the light trapping structure 2 on the preset plane have been illustrated above. In a practical application, the shape of the projection of the absorption structure 3 on the preset plane also includes a variety of cases.

In an embodiment, as illustrated in FIG. 1 to FIG. 2, the shape of the projection of the outer sidewalls of the light trapping structure 2 on the preset plane is the same as the shape of the projection of the absorption structure 3 on the preset plane. The incident light propagates annularly in the light trapping structure 2 and the germanium absorption region. Since the sizes of the light trapping structure 2 and the germanium absorption region may be very small and still satisfy the propagation requirements, based on this, the size of the photodetector may also be very small, and thus the parasitic parameters of the photodetector will be very small, such that the germanium-silicon waveguide-type photodetector has a higher bandwidth. Therefore, the germanium-silicon waveguide-type photodetector may balance a high bandwidth and a high responsivity simultaneously, which has obvious advantages.

In a practical application, the shape of the projection of the outer sidewalls of the light trapping structure 2 on the preset plane may be different from the shape of the projection of the absorption structure 3 on the preset plane.

In the above multiple embodiments, the sides, on which the outer sidewalls of the light trapping structure and the absorption structure are positioned, adopt structures such as circular, optimally deformed circular-like or polygonal structures, which may confine light to be stably transmitted within an enclosed structure and reduce the excitation to high-order modes of the incident light during the propagation process in the light trapping structure and the absorption structure. In this way, the leakage of light may be reduced, and thereby the responsivity of the photodetector is improved.

It is to be noted that the solutions provided by the embodiments of the disclosure apply to germanium-silicon waveguide-type photodetectors, and in addition, may also apply to photodetectors of the semiconductor material system, such as indium gallium arsenic/indium phosphorus (InGaAs/InP) series materials, aluminum gallium arsenic/gallium aluminum (AlGaAs/GaAl) series materials, gallium nitride (GaN) series materials, silicon carbide (SiC), or the like.

The above are only specific implementations of the disclosure, but the scope of protection of the disclosure is not limited thereto. Any variations or replacements apparent to those skilled in the art within the technical scope disclosed by the disclosure shall fall within the scope of protection of the disclosure. Therefore, the scope of protection of the disclosure shall be subject to the scope of protection of the claims.

### INDUSTRIAL APPLICABILITY

With the photodetector provided by the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure through the light trapping structure. Furthermore, the sides, on which the outer sidewalls of the light trapping structure and the absorption structure are positioned, adopt structures such as circular, optimally deformed circular-like or polygonal structures, which may confine light to be stably transmitted within an enclosed structure and reduce the excitation to high-order modes of the incident light during the propagation process in the light trapping structure and the absorption structure. In this way, the leakage of light may be reduced, and thereby the responsivity of the photodetector is improved. In addition, in the light trapping structure, the incident light can not escape from the light trapping structure in the first direction due to the total internal reflection effect of the sidewalls, and finally all of the incident light is coupled into the absorption structure. In the absorption structure, the incident light will also be confined within the absorption structure due to the total internal reflection effect of the sidewalls. In other words, the incident light propagates annularly in the light trapping structure and the absorption structure until the incident light is completely absorbed. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. In addition, in the embodiments of the disclosure, by setting the first electrode structure inside the light trapping structure, the contact between the absorption structure and the first electrode structure may be avoided, thereby reducing light loss generated by the contact between the absorption structure and the first electrode structure, and further improving the responsivity of the photodetector. Therefore, the photodetector provided by the embodiments of the disclosure may balance a high bandwidth and a high responsivity.

1. A photodetector, comprising a slab structure, a waveguide structure, a light trapping structure, an absorption structure, a first electrode structure and a second electrode structure, wherein
the waveguide structure extends into the light trapping structure; a first side, on which a first sidewall of the waveguide structure is positioned, is tangent to a second side, on which a second sidewall of outer sidewalls of the light trapping structure is positioned; and the waveguide structure is configured to import incident light into the light trapping structure in a direction tangent to the second side;
the imported light is confined to travel annularly within the light trapping structure by total internal reflection of sidewalls of the light trapping structure, and the imported light is coupled into the absorption structure through the light trapping structure;
the absorption structure is at least partially positioned on the light trapping structure; the coupled light is confined to travel annularly within the absorption structure by total internal reflection of sidewalls of the absorption structure, and the coupled light is converted into electrons and holes;
the slab structure surrounds the waveguide structure and the light trapping structure; and
the first electrode structure is positioned inside the light trapping structure; the second electrode structure is positioned outside the light trapping structure and is in contact with the light trapping structure; the first electrode structure and the second electrode structure are configured to collect electrons or holes flowing via the absorption structure and the light trapping structure; and the first electrode structure and the second electrode structure collect different types of carriers.

2. The photodetector of claim 1, wherein the light trapping structure comprises a first doped region and a second doped region surrounding the first doped region; and a doping type of the first doped region is opposite to a doping type of the second doped region;
the first electrode structure is positioned inside the first doped region and is in contact with the first doped region, and the first electrode structure is configured to collect electrons or holes flowing via the absorption structure and the first doped region; and
the second electrode structure is configured to collect electrons or holes flowing via the absorption structure and the second doped region.

3. The photodetector of claim 2, further comprising an intrinsic region positioned between the first doped region and the second doped region, wherein
a material of the intrinsic region is the same as a material of the light trapping structure; or
the material of the intrinsic region is the same as a material of the absorption structure.

4. The photodetector of claim 2, further comprising a first intrinsic region and a second intrinsic region that are positioned between the first doped region and the second doped region, wherein the first intrinsic region and the second intrinsic region are sequentially stacked along a direction of a thickness of the light trapping structure; and
a material of the first intrinsic region is the same as a material of the light trapping structure; and a material of the second intrinsic region is the same as a material of the absorption structure.

5. The photodetector of claim 3, wherein a sum of projections of the first doped region, the intrinsic region, and the second doped region on a preset plane covers a projection of the absorption structure on the preset plane; and the projection of the absorption structure on the preset plane covers the projection of the intrinsic region on the preset plane; and
the preset plane is perpendicular to a direction of a thickness of the light trapping structure.

6. The photodetector of claim 2, wherein
the first electrode structure comprises a first electrode, a first electrode contact region, and a third doped region; the third doped region is positioned inside the first doped region and is in contact with the first doped region; the first electrode contact region is positioned on a surface of the third doped region and a region with a certain depth downward from the surface of the third doped region, the first electrode is positioned on the first electrode contact region; and the first electrode is configured to collect electrons or holes flowing sequentially along the absorption structure, the first doped region, the third doped region, and the first electrode contact region; and
the second electrode structure comprises a second electrode, a second electrode contact region, and a fourth doped region; the fourth doped region surrounds the light trapping structure, the second electrode contact region is positioned on a surface of the fourth doped region and a region with a certain depth downward from the surface of the fourth doped region, the second electrode is positioned on the second electrode contact region; and the second electrode is configured to collect electrons or holes flowing sequentially along the absorption structure, the second doped region, and the fourth doped region.

7. The photodetector of claim 6, wherein a doping concentration of the second doped region is less than or equal to a doping concentration of the fourth doped region, the doping concentration of the fourth doped region is less than a doping concentration of the second electrode contact region, a doping concentration of the first doped region is less than or equal to a doping concentration of the third doped region, and the doping concentration of the third doped region is less than a doping concentration of the first electrode contact region.

8. The photodetector of claim 6, wherein the first electrode contact region is remote from the absorption structure, a thickness of the third doped region is less than or equal to a thickness of the light trapping structure; and a thickness of the waveguide structure is the same as the thickness of the light trapping structure.

9. The photodetector of claim 1, wherein
a shape of a projection of the waveguide structure on a preset plane comprises an elongated shape;
a shape of a projection of the outer sidewalls of the light trapping structure on the preset plane comprises an enclosed shape formed by at least one of at least one straight line or at least one curve, and an angle formed by the second side, on which the second sidewall of the outer sidewalls of the light trapping structure is positioned, and a third side, on which a third sidewall of the outer sidewalls of the light trapping structure is positioned, is an obtuse angle; and
the third sidewall is a sidewall where the incident light is reflected for a first time after the incident light enters the light trapping structure.

10. The photodetector of claim 9, wherein the shape of the projection of the outer sidewalls of the light trapping structure on the preset plane comprises one of:
a circle;
an enclosed shape formed by connecting a plurality of curves;
an enclosed shape formed by connecting a plurality of straight lines and a plurality of curves; or
a polygon.

11. The photodetector of claim 4, wherein a sum of projections of the first doped region, the first intrinsic region, the second intrinsic region, and the second doped region on a preset plane covers a projection of the absorption structure on the preset plane; and the projection of the absorption structure on the preset plane covers the projection of the first intrinsic region and the second intrinsic region on the preset plane; and
the preset plane is perpendicular to a direction of a thickness of the light trapping structure.
